(19) United States
(12) Patent Application Publication
(10) Pub. No.: US 2026/0015715 A1
(43) Pub. Date: Jan. 15, 2026

(54) VANADIUM PRECURSOR COMPOUND FOR THIN FILM DEPOSITION AND METHOD OF FORMING THIN FILM CONTAINING VANADIUM USING THE SAME

(71) Applicant: EGTM Co., Ltd., Suwon-si (KR)

(72) Inventors: Woong Jin Choi, Suwon-si (KR); Kun Hee Kim, Hwaseong-si (KR); Sun Young Baik, Incheon (KR); Shin Beom Kim, Suwon-si (KR); Sung Jun Ji, Suwon-si (KR); Tae Young Lee, Suwon-si (KR); Kyu Ho Cho, Suwon-si (KR)

(21) Appl. No.: 19/232,445

(22) Filed: Jun. 9, 2025

(30) Foreign Application Priority Data
Jul. 10, 2024 (KR) 10-2024-0090916

(51) Int. Cl. C23C 16/18; C23C 16/455

(52) U.S. Cl. CPC C23C 16/18; C23C 16/45553

(57) ABSTRACT

An embodiment of the present disclosure provides a vanadium precursor compound represented by Chemical Formula 1 or 2.

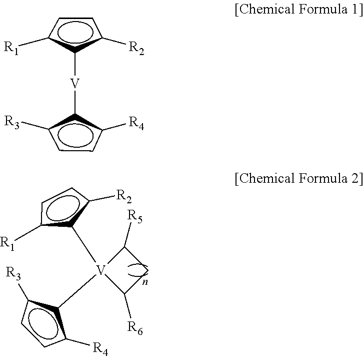

(In Chemical Formula 1, R₁, R₂, R₃ and R₄ are each independently selected from hydrogen, a linear alkyl group having 1 to 6 carbon atoms and a branched alkyl group having 3 to 4 carbon atoms, and in Chemical Formula 2, n is an integer of 0 to 4, a ring including a vanadium element is a heterocycloalkyl group or a heterocycloalkene group, and R₁, R₂, R₃, R₄, R₅ and R₆ are each independently selected from hydrogen, a linear alkyl group having 1 to 6 carbon atoms and a branched alkyl group having 3 to 6 carbon atoms.)

### CROSS-REFERENCE TO RELATED APPLICATION(S)

This application claims the priority of Korean Patent Application No. 10-2024-0090916 filed on Jul. 10, 2024, in the Korean Intellectual Property Office, the disclosure of which is incorporated herein by reference.

### BACKGROUND

### Field

The present disclosure relates to a vanadium precursor compound and a method of forming a thin film containing vanadium using the same, and more particularly, to a vanadium precursor compound having excellent thermal stability and a high vapor pressure, which is advantageous in a deposition process, and a method of forming a thin film containing vanadium using the same.

### Description of the Related Art

With the development of electronic technology, the demand for miniaturization and lightweighting of electronic devices used in various electronic devices is rapidly increasing. Various physical and chemical deposition methods have been proposed to form fine electronic devices, and various studies have been conducted to manufacture various electronic devices, such as metal thin films, metal oxide thin films, or metal nitride thin films using these deposition methods.

In the manufacturing of semiconductor devices, thin films containing Group 5 metal compounds are generally formed using a metal organic chemical vapor deposition (MOCVD) or atomic layer deposition (ALD) process.

Compared to the MOCVD process, the ALD process has advantages of having excellent step coverage due to a selflimiting reaction, and avoiding deterioration of device characteristics by thermal diffusion due to a relatively low-temperature process.

In order to deposit a thin film containing vanadium (V) among Group 5 metal compounds, it is very important to select a precursor compound suitable for the deposition process. Currently, various types of vanadium precursor compounds exist in the semiconductor industry.

However, conventional vanadium precursor compounds do not have high thermal stability, and the thin film containing vanadium formed using the vanadium precursor compounds through the deposition process had a problem of a high impurity content. As a result, it was difficult to form a thin film containing vanadium required for next-generation semiconductor devices.

### SUMMARY

An object of the present disclosure is to provide a vanadium precursor compound that is suitable for thin film growth, has strong thermal stability and a high vapor pressure, and exists in a liquid state at room temperature, thereby solving process problems caused by using conventional precursor compounds.

Another object of the present disclosure is to provide a vanadium precursor compound for thin film deposition capable of providing a high-quality, uniform thin film with a low content of impurities such as carbon using a vanadium precursor compound.

The objects of the present disclosure are not limited to the aforementioned objects, and other objects, which are not mentioned above, will be apparent to those skilled in the art from the following description.

An embodiment of the present disclosure provides a vanadium precursor compound represented by Chemical Formula 1 or 2.

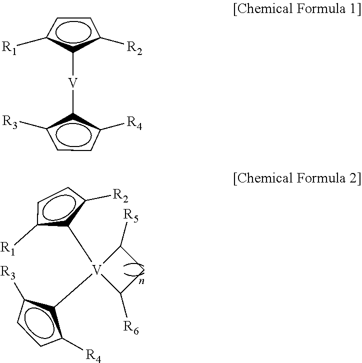

(In Chemical Formula 1, R₁, R₂, R₃ and R₄ are each independently selected from hydrogen, a linear alkyl group having 1 to 6 carbon atoms and a branched alkyl group having 3 to 4 carbon atoms, and in Chemical Formula 2, n is an integer of 0 to 4, a ring including a vanadium element is a heterocycloalkyl group or a heterocycloalkene group, and R₁, R₂, R₃, R₄, R₅ and R₆ are each independently selected from hydrogen, a linear alkyl group having 1 to 6 carbon atoms and a branched alkyl group having 3 to 6 carbon atoms.)

Another embodiment of the present disclosure provides a method of forming a thin film containing vanadium including depositing the thin film on a substrate through a metal organic chemical vapor deposition (MOCVD) process or an atomic layer deposition (ALD) process using the vanadium precursor compound.

Details of other embodiments will be included in the detailed description of the invention and the accompanying drawings.

According to an embodiment of the present disclosure, the vanadium precursor compound includes a cyclopentadiene ligand substituted with an alkyl group, exists in a liquid state at room temperature, and has a high vapor pressure, which is advantageous for a deposition process. In particular, the vanadium precursor compound according to an embodiment of the present disclosure has an advantage of having a high vapor pressure and excellent thermal stability because an alkyl group is asymmetrically substituted.

In addition, the vanadium thin film formed by depositing the vanadium precursor compound according to an embodiment of the present disclosure has an advantage of having a low content of impurities such as carbon and having uniform physical properties and thickness.

The effects according to the present disclosure are not limited by the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a graph showing a result of thermal gravimetric analysis (TGA) of a vanadium precursor compound according to Example 1;

FIG. 2 is a graph showing a result of thermal gravimetric analysis (TGA) of a vanadium precursor compound according to Example 2;

FIG. 3 is a graph showing a result of thermal gravimetric analysis (TGA) of a vanadium precursor compound according to Example 3;

FIG. 4 is a graph showing a result of thermal gravimetric analysis (TGA) of a vanadium precursor compound according to Comparative Example 1;

FIG. 5 is a graph showing a result of differential scanning calorimetry (DSC) of a vanadium precursor compound according to Example 1;

FIG. 6 is a graph showing a result of differential scanning calorimetry (DSC) of a vanadium precursor compound according to Example 2;

FIG. 7 is a graph showing a result of differential scanning calorimetry (DSC) of a vanadium precursor compound according to Example 3; and

FIG. 8 is a graph showing a result of differential scanning calorimetry (DSC) of a vanadium precursor compound according to Comparative Example 2.

### DETAILED DESCRIPTION OF THE EMBODIMENT

Advantages and features of the present disclosure, and methods for accomplishing the same will be more clearly understood from exemplary embodiments to be described below in detail with reference to the accompanying drawings. However, the present disclosure is not limited to the following embodiments but may be implemented in various different forms. The embodiments are provided only to complete the disclosure of the present disclosure and to fully provide a person having ordinary skill in the art to which the present disclosure pertains with the category of the invention, and the present disclosure will be defined only by the appended claims.

In describing the present disclosure, a detailed description of related known technologies will be omitted if it is determined that they unnecessarily make the gist of the present disclosure unclear. The terms such as “including”, “having”, and “consisting of” used herein are generally intended to allow other components to be added unless the terms are used with the term “only”. When a component is expressed in a singular form, the singular form may include a plural form unless clearly stated otherwise.

Components are interpreted to include an ordinary error range even if not expressly stated.

Throughout the present specification, the term “room temperature” means a temperature of 15° C. to 30° C., or 20° C. to 27° C.

A vanadium precursor compound according to an embodiment of the present disclosure may be represented by Chemical Formula 1 or 2.

First, Chemical Formula 1 will be described.

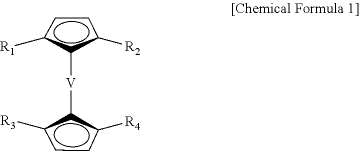

In Chemical Formula 1, R₁, R₂, R₃, and R₄ may each independently be selected from hydrogen, a linear alkyl group having 1 to 6 carbon atoms, and a branched alkyl group having 3 to 4 carbon atoms.

In the case of vanadocene (or bis (cyclopentadienyl) vanadium) in which vanadium is interposed between two cyclopentadienyl groups, the vanadocene is a reactive molecule and has the characteristics of low stability, a low vapor pressure, and easy solidification at room temperature. Accordingly, vanadocene compounds have been difficult to use in a deposition process for forming a thin film containing vanadium.

According to one embodiment of the present disclosure, the vanadium precursor compound has two cyclopentadienyl groups each having two alkyl substituents. Accordingly, the vanadium precursor compound has a high vapor pressure and may exist in a liquid state at room temperature.

For example, in Chemical Formula 1, R₁ and R₂ may be different from each other, and R₃ and R₄ may be different from each other. Such a compound includes a cyclopentadienyl group substituted in an asymmetric structure and thus has advantages of having better thermal stability, existing in a liquid state at room temperature, and having a high vapor pressure. Accordingly, according to an embodiment of the present disclosure, the vanadium precursor compound represented by Chemical Formula 1 is advantageous for use in a deposition process. In addition, the vanadium precursor compound may form a thin film containing vanadium with high reproducibility.

For example, in Chemical Formula 1, at least one of R₁ and R₂ may be selected from a linear alkyl group having 1 to 6 carbon atoms and a branched alkyl group having 3 to 4 carbon atoms, and at least one of R₃ and R₄ may be selected from a linear alkyl group having 1 to 6 carbon atoms and a branched alkyl group having 3 to 4 carbon atoms.

Specifically, the vanadium precursor compound may be represented by the following Chemical Formula 3 or 4.

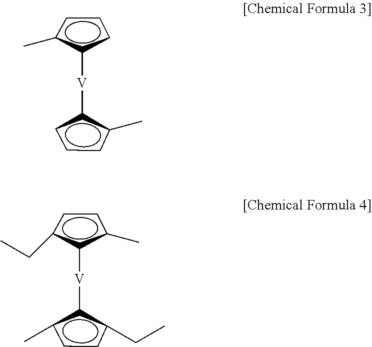

Such a vanadium precursor compound has a structure including two cyclopentadienyl groups, each having two alkyl substituents, and includes each of the two cyclopentadienyl groups having two alkyl substituents substituted in an asymmetrical structure to have excellent thermal stability, exist in a liquid state at room temperature, and have a high vapor pressure. In the case of using such a vanadium precursor compound, a deposition process may be facilitated, and a thin film containing vanadium formed by the deposition process may have high-quality characteristics with reduced impurity content and uniform physical properties.

According to another embodiment of the present disclosure, the vanadium precursor compound may be represented by the following Chemical Formula 2.

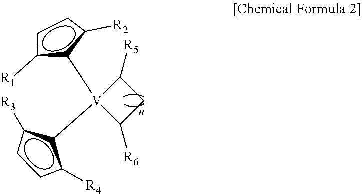

The vanadium precursor compound represented by Chemical Formula 2 further includes a ligand having a ring structure formed by including a vanadium element, compared to the vanadium precursor compound represented by Chemical Formula 1.

In Chemical Formula 2, n may be an integer of 0 to 4. That is, the ring formed by including the vanadium element may be a heterocycloalkyl group or heterocycloalkene group having 2 to 6 carbon atoms.

At this time, the heterocycloalkyl group or the heterocycloalkene group may be further substituted with R₅ and R₆.

In Chemical Formula 2, R₁, R₂, R₃, R₄, R₅ and R₆ may each independently be selected from hydrogen, a linear alkyl group having 1 to 6 carbon atoms, and a branched alkyl group having 3 to 6 carbon atoms.

For example, in Chemical Formula 2, R₁ and R₂ may be different from each other, and R₃ and R₄ may be different from each other. In this case, as described above, the vanadium precursor compound includes the cyclopentadienyl group substituted in the asymmetric structure and thus has advantages of having excellent thermal stability, existing in a liquid state at room temperature, and having a high vapor pressure. Accordingly, according to an embodiment of the present disclosure, the vanadium precursor compound represented by Chemical Formula 2 is advantageous for use in a deposition process. In addition, the vanadium precursor compound may form a thin film containing vanadium with high reproducibility.

For example, in Chemical Formula 2, R₅ and R₆ may be different from each other. In this case, a substituent bound to the heterocycloalkyl group or heterocycloalkene group containing the vanadium element may have an asymmetric structure, so that the thermal stability may be further improved.

In Chemical Formula 2, at least one of R₁ and R₂ may be selected from a linear alkyl group having 1 to 6 carbon atoms and a branched alkyl group having 3 to 4 carbon atoms, at least one of R₃ and R₄ may be selected from a linear alkyl group having 1 to 6 carbon atoms and a branched alkyl group having 3 to 4 carbon atoms, and R₅ and R₆ may be selected from a linear alkyl group having 1 to 6 carbon atoms and a branched alkyl group having 3 to 4 carbon atoms.

In Chemical Formula 2, the ring including the vanadium element may be a heterocycloalkene group including one or more double bonds. In this case, the stability of the precursor compound is more excellent, and may facilitate the deposition process.

Specifically, for example, the vanadium precursor compound may be represented by the following Chemical Formula 5.

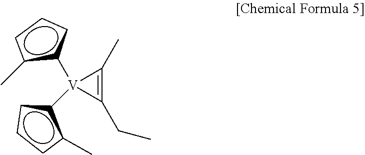

Such a vanadium precursor compound includes a cyclopentadienyl group substituted in an asymmetric structure and thus has advantages of having excellent thermal stability, existing in a liquid state at room temperature, and having a high vapor pressure.

In addition, in the case of using such a vanadium precursor compound, a deposition process may be facilitated, and a thin film containing vanadium formed by the deposition process may have high-quality characteristics with reduced impurity content and uniform physical properties.

The vanadium precursor compound represented by Chemical Formula 1 or 2 according to an embodiment of the present disclosure exists in a liquid state at room temperature, making it easy to store and handle, and may be advantageously applied to form a thin film using a deposition process.

Accordingly, the compound according to an embodiment of the present disclosure may be advantageously used as a precursor for manufacturing a thin film containing vanadium through an MOCVD process or an ALD process.

Herein, the compound represented by Chemical Formula 1 or 2 may be used as a precursor composition for depositing a thin film containing vanadium.

Hereinafter, a method of forming a thin film containing vanadium according to an embodiment of the present disclosure will be described in detail. The method of forming the thin film containing vanadium uses the above-described vanadium precursor compound, and the duplicated description related to the vanadium precursor compound will be omitted.

In the method of forming the thin film containing vanadium according to an embodiment of the present disclosure, a thin film is deposited on a substrate through a deposition process using a vanadium precursor compound represented by Chemical Formula 1 or 2.

The deposition process may be performed by an atomic layer deposition (ALD) process or a chemical vapor deposition (CVD) process, for example, a metal organic chemical vapor deposition (MOCVD) process.

For example, the deposition process may be performed at 50° C. to 700° C. Within the range, the stability of the compound is not reduced, and a thin film with uniform physical properties may be formed.

Hereinafter, the deposition process will be described in detail.

First, the vanadium precursor compound represented by Chemical Formula 1 or 2 is transferred onto the substrate. For example, the vanadium precursor compound may be supplied onto the substrate by a bubbling method, a vapor phase mass flow controller method, a direct gas injection (DGI) method, a direct liquid injection (DLI) method, a liquid transfer method to be dissolved and transferred in an organic solvent, and the like.

If necessary, the vanadium precursor compound may be supplied with carrier gas or dilution gas.

The carrier gas has no reactivity with the vanadium precursor compound and is lighter than the vanadium precursor compound to easily transfer the vaporized vanadium precursor compound to a reaction chamber.

The dilution gas has no reactivity with the vanadium precursor compound, so as not to cause side reactions, and the flow rate thereof may be controlled to easily control the reaction such as a growth rate of a thin film, etc. For example, each of the carrier gas and the dilution gas may be at least one selected from argon (Ar), nitrogen (N₂), helium (He), and hydrogen (H₂).

For example, the vanadium precursor compound may be mixed with carrier gas or dilution gas containing at least one selected from argon (Ar), nitrogen (N₂), helium (He), and hydrogen (H₂) to be transferred onto the substrate by a bubbling method or a direct gas injection method.

In the deposition process for forming the thin film containing vanadium, the reaction gas may be supplied as needed. The reaction gas may be supplied in a step of depositing the thin film.

For example, the reaction gas may be used with at least one selected from gases containing oxygen, such as water vapor (H₂O), oxygen (O₂), ozone (O₃), and hydrogen peroxide (H₂O₂).

As another example, the reaction gas may be used with at least one selected from gases containing nitrogen, such as ammonia (NH₃), hydrazine (N₂H₄), nitrous oxide (N₂O), and nitrogen (N₂).

After the vanadium precursor compound is supplied to the substrate, when energy such as thermal energy, plasma, or electrical bias is applied, a thin film containing vanadium is formed by a chemical reaction.

When the thin film having a desired thickness is formed, the method may include purging a reaction chamber with inert gas such as argon (Ar), nitrogen (N₂), helium (He), and/or hydrogen (H₂) to remove any precursor compounds, reaction gases, etc. that remain unreacted.

The thin film containing vanadium manufactured by the method of forming the thin film according to an embodiment of the present disclosure may effectively reduce the amount of impurities such as carbon, thereby providing a high-quality thin film.

Hereinafter, a vanadium precursor compound according to the present disclosure will be described in more detail through the following Examples. However, these Examples are only presented to aid the understanding of the present disclosure, and the present disclosure is not limited to the following Examples.

### Example 1

In a 1000 mL flame-dried Schlenk flask, 20.0 g (0.127 mol, 1 equivalent) of vanadium trichloride VCl₃ and 500 mL of tetrahydrofuran were added, and then refluxed at 70° C. for 12 hours. Then, 19.5 g (0.299 mol, 2.35 equivalents) of Zn powder was added, and then stirred at room temperature for 12 hours. Then, a solvent was removed under reduced pressure. Thereafter, 300 mL of dichloromethane was added, and then stirred for 1 hour. Thereafter, in order to separate a substance dissolved in dichloromethane, the solvent was removed under reduced pressure after filtering to obtain a green solid compound represented by [V₂(Cl)₃(THF)₆]₂[Zn₂Cl₆]. Thereafter, the green solid was fully dissolved in 400 mL of a THF solvent, and 200 mL of a 0.267 mol (2.1 equivalents) solution of sodium methylcyclopentadienide (NaMeCp) dissolved in THF was added dropwise at −20° C. or lower, and then the reaction solution was refluxed at 70° C. for 12 hours. Thereafter, the solvent was removed under reduced pressure, and then distilled under reduced pressure to obtain 7.5 g of a purple liquid compound, (MeCp) 2V of Chemical Formula 3.

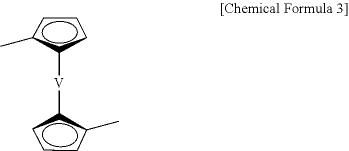

### Example 2

In a 1000 mL flame-dried Schlenk flask, 20.0 g (0.127 mol, 1 equivalent) of vanadium trichloride VCl₃ and 500 mL of tetrahydrofuran were added, and then refluxed at 70° C. for 12 hours. Then, 19.5 g (0.299 mol, 2.35 equivalents) of Zn powder was added, and then stirred at room temperature for 12 hours. Then, a solvent was removed under reduced pressure. Thereafter, 300 mL of dichloromethane was added, and then stirred for 1 hour. Thereafter, in order to separate a substance dissolved in dichloromethane, the solvent was removed under reduced pressure after filtering to obtain a green solid compound represented by [V₂(Cl)₃(THF)₆]₂[Zn₂Cl₆]. Thereafter, the green solid was fully dissolved in 400 mL of a THF solvent, and 200 mL of a 0.267 mol (2.1 equivalents) solution of lithium ethyl methyl cyclopentadienide (LiEtMeCp) dissolved in THF was added dropwise at −20° C. or lower, and then the reaction solution was refluxed at 70° C. for 12 hours. Thereafter, the solvent was removed under reduced pressure, and then distilled under reduced pressure to obtain 8.8 g of a purple liquid compound, (EtMeCp) 2V of Chemical Formula 4.

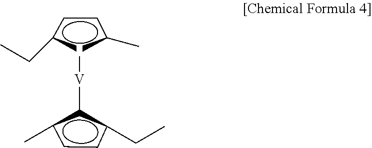

### Example 3

In a 500 mL flame-dried Schlenk flask, 20.0 g (0.127 mol) of (MeCp) 2V and 200 mL of toluene were added and then stirred for 1 hour. Then, 6.6 g (0.127 mol) of 2-pentyne was added dropwise and then stirred for 12 hours. Thereafter, the solvent was removed under reduced pressure, and then distilled under reduced pressure to obtain 9.2 g of a purple liquid compound, (MeCp) 2V (2-pentyne) of Chemical Formula 5.

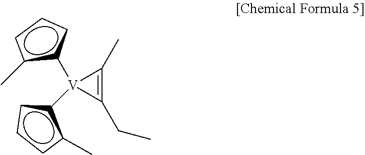

### Comparative Example 1

In a 1000 mL flame-dried Schlenk flask, 20.0 g (0.127 mol, 1 equivalent) of vanadium trichloride VCl₃ and 500 mL of tetrahydrofuran were added, and then refluxed at 70° C. for 12 hours. Then, 19.5 g (0.299 mol, 2.35 equivalents) of Zn powder was added, and then stirred at room temperature for 12 hours. Then, a solvent was removed under reduced pressure. Thereafter, 300 mL of dichloromethane was added, and then stirred for 1 hour. Thereafter, in order to separate a substance dissolved in dichloromethane, the solvent was removed under reduced pressure after filtering to obtain a green solid compound represented by [V₂(Cl)₃(THF)₆]₂[Zn₂Cl₆]. Thereafter, the green solid was fully dissolved in 400 mL of a THF solvent, and 200 mL of a 0.267 mol (2.1 equivalents) solution of NaCp dissolved in THF was added dropwise at −20° C. or lower, and then the reaction solution was refluxed at 70° C. for 12 hours. Thereafter, the solvent was removed under reduced pressure, and sublimated and purified under reduced pressure to obtain 5.5 g of a purple solid compound, Cp2V of Chemical Formula 6.

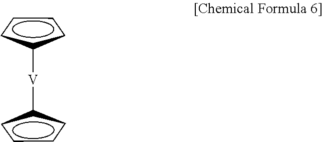

### Experimental Examples

### 1. Thermogravimetric Analysis (TGA)

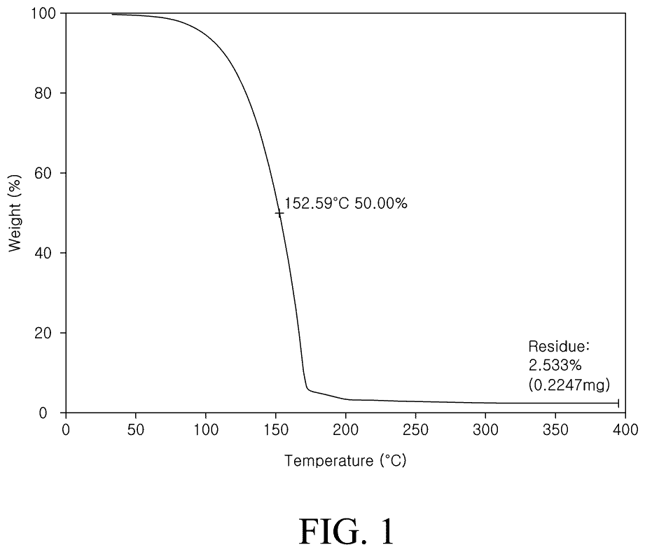

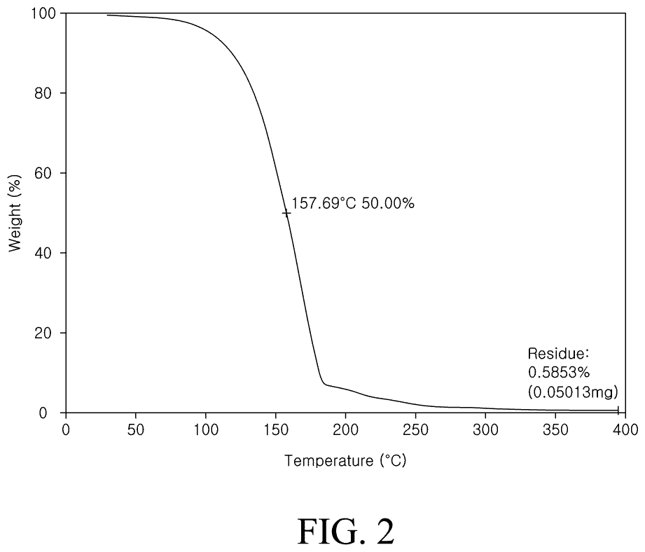

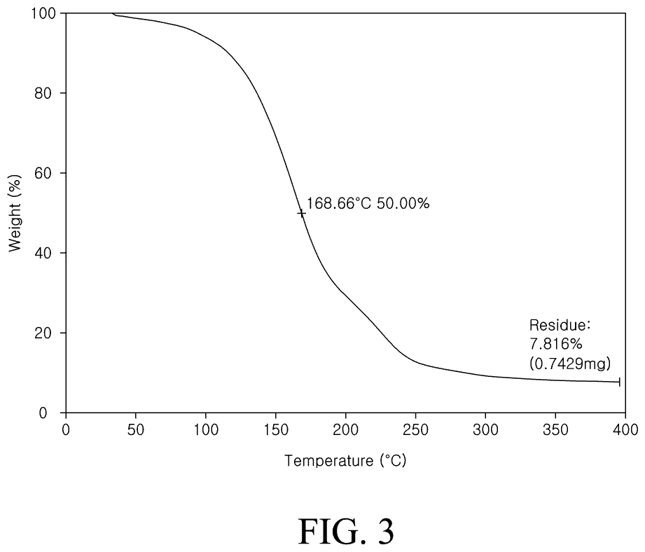

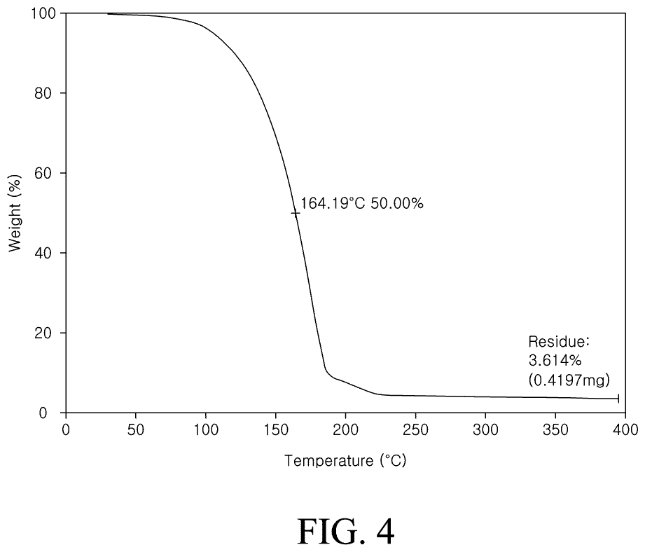

To determine the thermal properties of the compounds according to Examples 1, 2, and 3,and Comparative Example 1, thermogravimetric analysis (TGA) was performed. First, the TGA equipment was stored in a nitrogen glove box where the moisture and oxygen content were maintained at less than 1 ppm. Then, 10 mg of a sample was placed in a crucible, and then measured while heating from 30° C. to 400° C. at a rate of 10° C./min. The mass loss of the sample was monitored as a function of the crucible temperature. The results were shown in FIGS. 1 to 4 and Table 1. FIG. 1 is a graph showing a result of thermal gravimetric analysis (TGA) of a vanadium precursor compound according to Example 1, FIG. 2 is a graph showing a result of thermal gravimetric analysis (TGA) of a vanadium precursor compound according to Example 2, FIG. 3 is a graph showing a result of thermal gravimetric analysis (TGA) of a vanadium precursor compound according to Example 3, and FIG. 4 is a graph showing a result of thermal gravimetric analysis (TGA) of a vanadium precursor compound according to Comparative Example 1.

### 2. Differential Scanning Calorimetry (DSC)

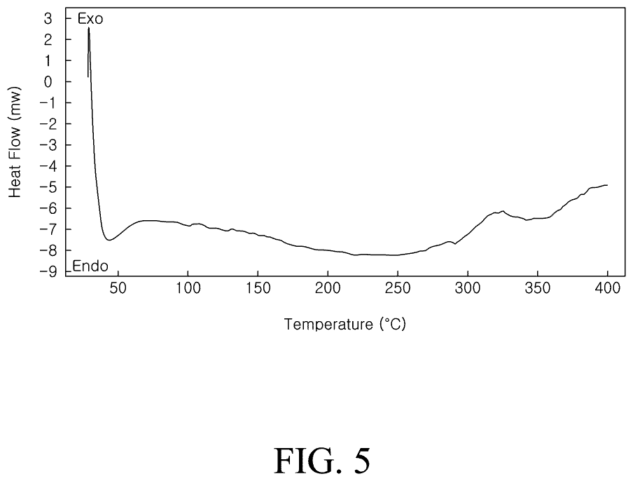

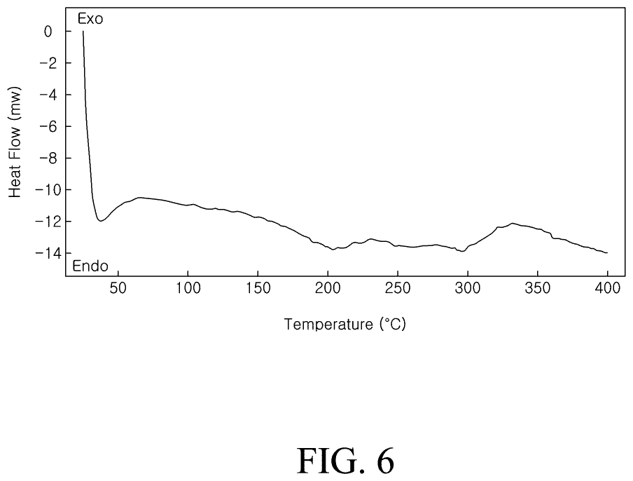

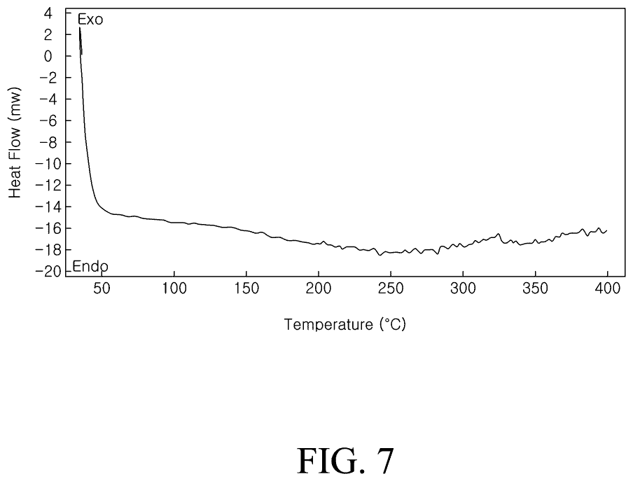

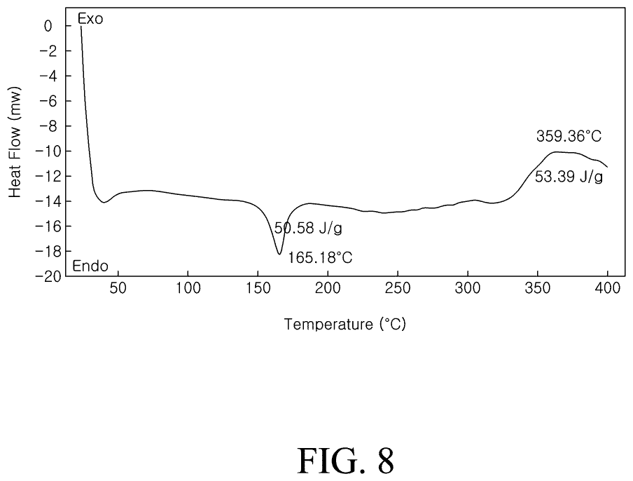

Differential scanning calorimetry was measured using a differential scanning calorimeter while heating from 30° C. to 400° C. at a rate of 10° C./min. The results were shown in FIGS. 5 to 8 and Table 1. FIG. 5 is a graph showing a result of differential scanning calorimetry (DSC) of a vanadium precursor compound according to Example 1, FIG. 6 is a graph showing a result of differential scanning calorimetry (DSC) of a vanadium precursor compound according to Example 2, FIG. 7 is a graph showing a result of differential scanning calorimetry (DSC) of a vanadium precursor compound according to Example 3, and FIG. 8 is a graph showing a result of differential scanning calorimetry (DSC) of a vanadium precursor compound according to Comparative Example 2.

### 3. Room Temperature State

A state of each compound at room temperature was visually inspected and shown in Table 1 below.

TABLE 1

| | | | | Comparative |
|---|---|---|---|---|
| | Example 1 | Example 2 | Example 3 | Example 1 |
| Structure | 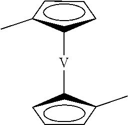 | 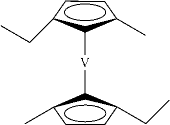 | 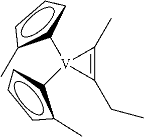 | 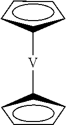 |
| T_{1/2} (° C.) | 152.59 | 157.69 | 169 | 164.19 |
| Td (° C.) | >400 | >400 | >400 | 359 |
| State at room | Liquid | Viscous liquid | Liquid | Crystalline solid |
| temperature | | | | |

Referring to Table 1 and FIGS. 1 to 8 together, it can be confirmed that the vanadium precursor compounds of Examples 1 to 3 exist in a liquid state at room temperature and have a thermal decomposition temperature of at least 50° C. or higher than that of Comparative Example 1. From this, it can be seen that the vanadium precursor compounds of Examples 1 to 3 have excellent thermal stability and exist in a liquid at room temperature, making it easy to supply reactants and control reactions during the deposition process.

Since the compound of Comparative Example 1 has a melting point of about 160° C., it can be confirmed that the vapor pressure is higher than that of Examples 1 and 2 due to a phase change, but since the compound of Comparative Example 1 exists in a crystalline solid at room temperature, it is not easy to supply reactants during a deposition process such as MOCVD or ALD, and the thermal decomposition temperature is considerably low at 359° C. Accordingly, it can be predicted that the vanadium thin film formed by depositing the compound of Comparative Example 1 will not have uniform physical properties and will have a high impurity content.

The compounds of Examples 1 to 3 contain cyclopentadiene ligands substituted in an asymmetric structure, and in this case, it can be confirmed that the compounds exist as liquids at room temperature due to a characteristic of a low melting point, unlike Comparative Example 1 in a solid state.

Meanwhile, when comparing the results of Examples 1 to 3, it can be confirmed that the compound of Example 3 is liquid at room temperature, has the highest vapor pressure, and has excellent thermal stability.

In addition, when comparing Examples 1 and 2, Example 2, which has two substituents, has a lower binding force between the vanadium element and the ligand compound than Example 1, which has one substituent bound to cyclopentadiene. Therefore, the compound of Example 2may contribute to reducing the content of unnecessary impurities during thin film formation.

A vanadium precursor compound and a method of forming a thin film containing vanadium according to various embodiments of the present disclosure may be described as follows.

A vanadium precursor compound according to an embodiment of the present disclosure is represented by the following Chemical Formula 1 or 2.

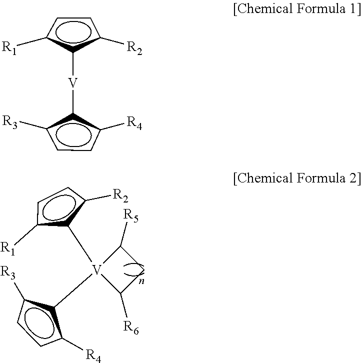

(In Chemical Formula 1, R₁, R₂, R₃ and R₄ are each independently selected from hydrogen, a linear alkyl group having 1 to 6 carbon atoms and a branched alkyl group having 3 to 4 carbon atoms, and in Chemical Formula 2, n is an integer of 0 to 4, a ring including a vanadium element is a heterocycloalkyl group or a heterocycloalkene group, and R₁, R₂, R₃, R₄, R₅ and R₆ are each independently selected from hydrogen, a linear alkyl group having 1 to 6 carbon atoms and a branched alkyl group having 3 to 6 carbon atoms.)

According to another feature of the present disclosure, in Chemical Formula 1, R₁ and R₂ may be different from each other, and R₃ and R₄ may be different from each other.

According to yet another feature of the present disclosure, in Chemical Formula 1, at least one of R₁ and R₂ may be selected from a linear alkyl group having 1 to 6 carbon atoms and a branched alkyl group having 3 to 4 carbon atoms, and in Chemical Formula 1, at least one of R₃ and R₄ may be selected from a linear alkyl group having 1 to 6 carbon atoms and a branched alkyl group having 3 to 4 carbon atoms.

According to yet another feature of the present disclosure, the vanadium precursor compound may be a compound represented by the following Chemical Formula 3 or 4.

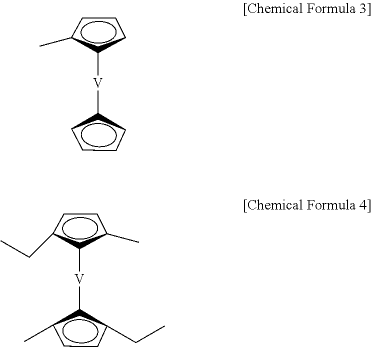

According to yet another feature of the present disclosure, in Chemical Formula 2, R₁ and R₂ may be different from each other, R₃ and R₄ may be different from each other, and R₅ and R₆ may be different from each other.

According to yet another feature of the present disclosure, in Chemical Formula 2, at least one of R₁ and R₂ may be selected from a linear alkyl group having 1 to 6 carbon atoms and a branched alkyl group having 3 to 4 carbon atoms, in Chemical Formula 2, at least one of R₃ and R₄ may be selected from a linear alkyl group having 1 to 6 carbon atoms and a branched alkyl group having 3 to 4 carbon atoms, and in Chemical Formula 2, R₅ and R₆ may be selected from a linear alkyl group having 1 to 6 carbon atoms and a branched alkyl group having 3 to 4 carbon atoms.

According to yet another feature of the present disclosure, in Chemical Formula 2, the ring including the vanadium element may be a heterocycloalkene group including one or more double bonds.

According to yet another feature of the present disclosure, the vanadium precursor compound may be represented by the following Chemical Formula 5.

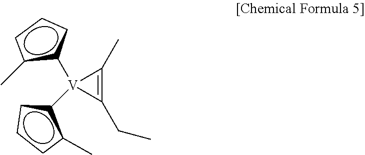

According to yet another feature of the present disclosure, the vanadium precursor compound may be in a liquid state at room temperature.

A method of forming a thin film containing vanadium according to an embodiment of the present disclosure includes a process of depositing a thin film on a substrate through a metal organic chemical vapor deposition (MOCVD) process or an atomic layer deposition (ALD) process using a vanadium precursor compound.

According to another feature of the present disclosure, the deposition process may be performed in the range of 50° C. to 700° C.

According to yet another feature of the present disclosure, the deposition process may include transferring the vanadium precursor compound to the substrate through one method selected from a bubbling method, a vapor phase mass flow controller (MFC) method, a direct gas injection (DGI) method, a direct liquid injection (DLI) method, and an organic solution supply method of dissolving and transferring the vanadium precursor compound in an organic solvent.

According to yet another feature of the present disclosure, the vanadium precursor compound may be transferred onto the substrate with carrier gas by the bubbling method, the direct gas injection method, or the direct liquid injection method, and the carrier gas may include at least one selected from argon (Ar), nitrogen (N₂), helium (He), and hydrogen (H₂).

According to yet another feature of the present disclosure, the deposition process may include supplying at least one reaction gas selected from water vapor (H₂O), oxygen (O₂), ozone (O₃), and hydrogen peroxide (H₂O₂), when forming the thin film containing vanadium.

According to yet another feature of the present disclosure, the deposition process may include supplying at least one reaction gas selected from ammonia (NH₃), hydrazine (N₂H₄), nitrous oxide (N₂O), and nitrogen (N₂), when forming the thin film containing vanadium.

Although the embodiments of the present disclosure have been described in detail with reference to the accompanying drawings, the present disclosure is not limited thereto and may be embodied in many different forms without departing from the technical concept of the present disclosure. Accordingly, the various embodiments disclosed in the present disclosure are not intended to limit the technical spirit but describe the present disclosure and the technical spirit of the present disclosure is not limited by the following embodiments. Therefore, it should be understood that the above-described embodiments are illustrative in all aspects and do not limit the present disclosure. The protective scope of the present disclosure should be construed on the basis of the appended claims, and all the technical ideas in the equivalent scope thereof should be construed as falling within the scope of the present disclosure.

What is claimed is:

1. A vanadium precursor compound represented by the following Chemical Formula 1 or 2: 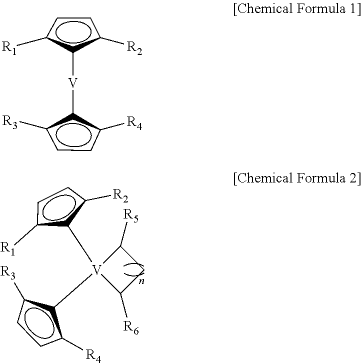
in Chemical Formula 1,
R₁, R₂, R₃ and R₄ are each independently selected from hydrogen, a linear alkyl group having 1 to 6 carbon atoms and a branched alkyl group having 3 to 4 carbon atoms, and
in Chemical Formula 2,
n is an integer of 0 to 4,
a ring including a vanadium element is a heterocycloalkyl group or a heterocycloalkene group, and
R₁, R₂, R₃, R₄, R₅ and R₆ are each independently selected from hydrogen, a linear alkyl group having 1 to 6 carbon atoms and a branched alkyl group having 3 to 6 carbon atoms.

2. The vanadium precursor compound of claim 1, wherein in Chemical Formula 1, R₁ and R₂ are different from each other, and R₃ and R₄ are different from each other.

3. The vanadium precursor compound of claim 1, wherein in Chemical Formula 1, at least one of R₁ and R₂ is selected from a linear alkyl group having 1 to 6 carbon atoms and a branched alkyl group having 3 to 4 carbon atoms, and
in Chemical Formula 1, at least one of R₃ and R₄ is selected from a linear alkyl group having 1 to 6 carbon atoms and a branched alkyl group having 3 to 4 carbon atoms.

4. The vanadium precursor compound of claim 1, wherein the vanadium precursor compound is represented by the following Chemical Formula 3 or 4:

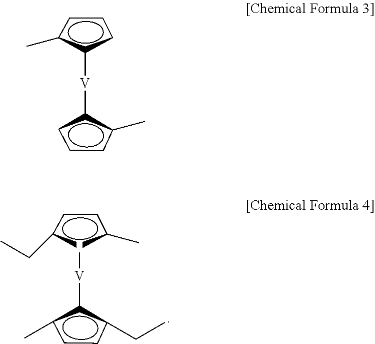

5. The vanadium precursor compound of claim 1, wherein in Chemical Formula 2, R₁ and R₂ are different from each other, R₃ and R₄ are different from each other, and R₅ and R₆ are different from each other.

6. The vanadium precursor compound of claim 1, wherein in Chemical Formula 2, at least one of R₁ and R₂ is selected from a linear alkyl group having 1 to 6 carbon atoms and a branched alkyl group having 3 to 4 carbon atoms,
in Chemical Formula 2, at least one of R₃ and R₄ is selected from a linear alkyl group having 1 to 6 carbon atoms and a branched alkyl group having 3 to 4 carbon atoms, and in Chemical Formula 2, R₅ and R₆ are selected from a linear alkyl group having 1 to 6 carbon atoms and a branched alkyl group having 3 to 4 carbon atoms.

7. The vanadium precursor compound of claim 1, wherein in Chemical Formula 2, the ring including the vanadium element is a heterocycloalkene group including one or more double bonds.

8. The vanadium precursor compound of claim 1, wherein the vanadium precursor compound is represented by the following Chemical Formula 5:

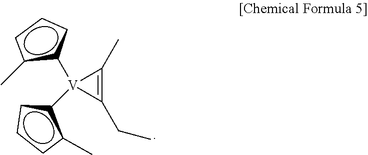

9. The vanadium precursor compound of claim 1, wherein the vanadium precursor compound is in a liquid state at room temperature.

10. A method of forming a thin film containing vanadium comprising depositing a thin film on a substrate through a metal organic chemical vapor deposition (MOCVD) process or an atomic layer deposition (ALD) process using the vanadium precursor compound of claim 1.

11. The method of forming the thin film containing vanadium of claim 10, wherein the deposition process is performed in a range of 50° C. to 700° C.

12. The method of forming the thin film containing vanadium of claim 10, wherein the deposition process includes transferring the vanadium precursor compound to the substrate through one method selected from a bubbling method, a vapor phase mass flow controller (MFC) method, a direct gas injection (DGI) method, a direct liquid injection (DLI) method, and an organic solution supply method of dissolving and transferring the vanadium precursor compound in an organic solvent.

13. The method of forming the thin film containing vanadium of claim 12, wherein the vanadium precursor compound is transferred onto the substrate with carrier gas by the bubbling method, the direct gas injection method, or the direct liquid injection method, and
the carrier gas includes at least one selected from argon (Ar), nitrogen (N₂), helium (He), and hydrogen (H₂).

14. The method of forming the thin film containing vanadium of claim 12, wherein the deposition process includes supplying at least one reaction gas selected from water vapor (H₂O), oxygen (O₂), ozone (O₃), and hydrogen peroxide (H₂O₂), when forming the thin film containing vanadium.

15. The method of forming the thin film containing vanadium of claim 12, wherein the deposition process includes supplying at least one reaction gas selected from ammonia (NH₃), hydrazine (N₂H₄), nitrous oxide (N₂O), and nitrogen (N₂), when forming the thin film containing vanadium.
